(19) United States
(12) Patent Application Publication
(10) Pub. No.: US 2025/0229306 A1
(43) Pub. Date: Jul. 17, 2025

(54) WAFER STORAGE CONTAINER CLEANING APPARATUS

(71) Applicant: SHIBAURA MECHATRONICS CORPORATION, Kanagawa (JP)

(72) Inventor: Yotaro FUKUOKA, Kanagawa (JP)

(21) Appl. No.: 19/011,990

(22) Filed: Jan. 7, 2025

(30) Foreign Application Priority Data
Jan. 12, 2024 (JP) 2024-003496

(51) Int. Cl. B08B 9/28; B08B 9/08; B08B 9/32

(52) U.S. Cl. CPC B08B 9/283; B08B 9/0826; B08B 9/32

(57) ABSTRACT

According to one embodiment, a wafer storage container cleaning apparatus includes: a cleaning chamber accommodating a body of a wafer storage container, the body including a storage space storing semiconductor wafers and an opening of the storage space; a stage inside the cleaning chamber, having a placement surface for disposing the body thereon, and supporting the body by the placement surface; a cleaning liquid supply supplying a cleaning liquid to inner and outer sides of the body to clean the inner and outer sides; a first drainage receiver receiving drainage after cleaning the inner side of the body, and discharging the received drainage to outside; a second drainage receiver receiving drainage after cleaning the outer side of the body, and discharging the received drainage to outside; and an exhaust to exhaust the storage space formed by the inner side of the body.

### CROSS-REFERENCE TO RELATED APPLICATIONS

This application is based on and claims priority from Japanese Patent Application No. 2024-003496, filed on Jan. 12, 2024, with the Japan Patent Office, the disclosure of which is incorporated herein in its entirety by reference.

### TECHNICAL FIELD

The present disclosure relates to a wafer storage container cleaning apparatus.

### BACKGROUND

In the related art, there are wafer storage container cleaning apparatuses, which clean and dry wafer storage containers such as front opening unified pods (FOUPs) or front opening shipping boxes (FOSBs) storing (accommodating) semiconductor wafers.

In a wafer storage container, when a door (lid unit) is opened and closed, or semiconductor wafers are carried into/out of the container, impurities (particles) may be attached to the wall surface surrounding the storage space in which the semiconductor wafers are stored (the inner side of the wafer storage container). Thus, a cleaning of at least the inner side of the wafer storage container is performed by a cleaning chamber of the wafer storage container cleaning apparatus. In the wafer storage container cleaning apparatus, it is desired to effectively reduce residual particles on the inner side of the wafer storage container (see, e.g., Japanese Patent Laid-Open Publication No. 2005-109523).

### SUMMARY

The present disclosure provides a wafer storage container cleaning apparatus, which may effectively reduce residual particles on the inner side of a wafer storage container.

According to an aspect of the present disclosure, a wafer storage container cleaning apparatus includes: a cleaning chamber that accommodates a body of a wafer storage container, the body including a storage space storing semiconductor wafers and an opening of the storage space; a stage disposed inside the cleaning chamber, having a placement surface on which the body is disposed in a state where the opening faces downward, and supporting the body by the placement surface; a cleaning liquid supply that supplies a cleaning liquid to an inner side of the body that is a wall surface surrounding the storage space, and an outer side of the body that is an outer wall surface of the body, thereby cleaning the inner side and the outer side of the body; a first drainage receiver receiving a drainage that is the cleaning liquid after cleaning the inner side of the body, and discharging the received drainage to an outside; a second drainage receiver receiving a drainage that is the cleaning liquid after cleaning the outer side of the body, and discharging the received drainage to the outside; and an exhaust that exhausts the storage space formed by at least the inner side of the body.

According to an embodiment of the present disclosure, residual particles on the inner side of the wafer storage container may be effectively reduced.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating an example of a schematic configuration of a wafer storage container cleaning apparatus according to an embodiment.

FIG. 2 is a front cross-sectional view schematically illustrating an example of a configuration of a cleaning chamber according to an embodiment.

FIG. 3 is a cross-sectional view taken along the line A-A in FIG. 2.

FIG. 4 is a view illustrating an example of a configuration of a support member according to an embodiment.

FIG. 5 is a view illustrating an example of a configuration of each unit provided in a flow path in which a drainage flows, at a further rear end than a first drainage receiving unit, according to an embodiment.

FIG. 6 is a flowchart illustrating an example of a process performed by a wafer storage container cleaning apparatus according to an embodiment.

FIG. 7 is a view illustrating an example of an exhaust performed by a wafer storage container cleaning apparatus according to an embodiment.

### DESCRIPTION OF EMBODIMENTS

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the wafer storage container cleaning apparatus of the present disclosure are described in detail with reference to the accompanying drawings. The wafer storage container cleaning apparatus of the present disclosure is not limited to the embodiments described herein below. Further, the embodiments and modifications thereof may be appropriately combined with each other within the scope that does not cause inconsistence. In the following embodiments, descriptions are made, assuming an example where a wafer storage container to be cleaned is a FOUP, but the wafer storage container to be cleaned is not limited thereto. For example, the wafer storage container to be cleaned may be a FOSB.

### Embodiments

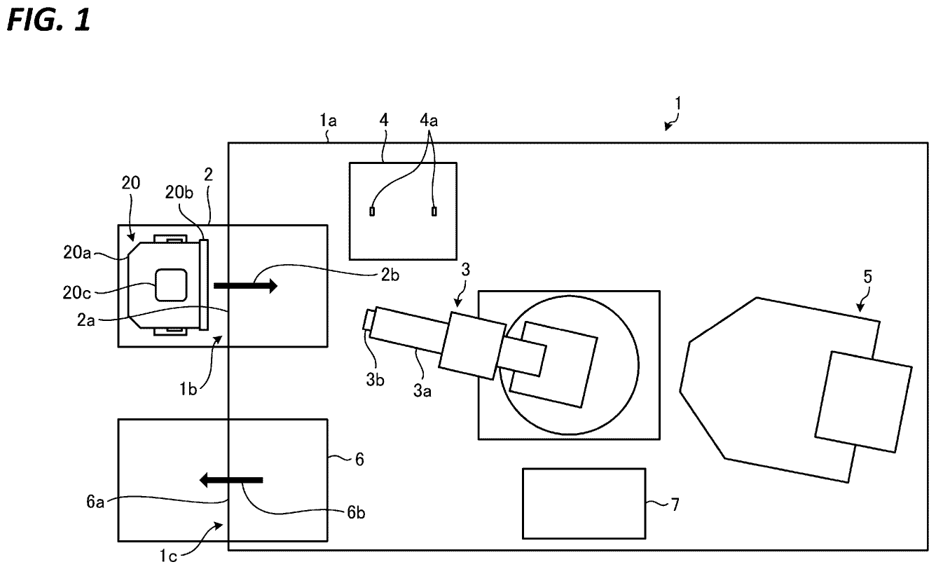

FIG. 1 is a plan view illustrating an example of a schematic configuration of a wafer storage container cleaning apparatus 1 according to an embodiment. In the present embodiment, a FOUP 20, which is an example of a wafer storage container to be cleaned, includes a body (FOUP main body) 20a and a door 20b. The body 20a has a storage space for storing semiconductor wafers. The door 20b is provided to be openable/closable with respect to an opening of the storage space. Further, a flange 20c is provided on the top of the body 20a. The flange 20c is a portion that is gripped (held) when the FOUP 20 is transported by, for example, an overhead hoist transport (OHT) or a robot 3. In the present embodiment, the inner wall surface of the body 20a that surrounds the storage space is referred to as the “inner side,” and the outer wall surface thereof is referred to as the “outer side.” That is, the inner side of the body 20a makes up the storage space. Similarly, in the state where the door 20b is connected to the body 20a, the portion of the door 20b facing the storage space is referred to as the “inner side,” and the portion of the door 20b facing the outside is referred to as the “outer side.”

The wafer storage container cleaning apparatus 1 is provided, for example, in a plant for manufacturing semiconductor wafers, to clean a wafer storage container. As illustrated in FIG. 1, the wafer storage container cleaning apparatus 1 includes a load port 2, a robot 3, a disassembly/connection stage 4, a cleaning chamber 5, an unload port 6, and a control unit 7.

The robot 3, the disassembly/connection stage 4, the cleaning chamber 5, and the control unit 7 are provided inside a casing 1a of the wafer storage container cleaning apparatus 1. Meanwhile, the load port 2 and the unload port 6 are provided across the inside and the outside of the casing 1a of the wafer storage container cleaning apparatus 1.

In the load port 2, the FOUP 20 that has been transported and disposed on the portion of the load port 2 outside the casing 1a by the OHT is moved in the direction indicated by the arrow 2b and carried into the casing 1a. A shutter 2a provided in the opening 1b of the casing 1a is opened when the FOUP 20 is carried in, and closed when the FOUP 20 is not carried in.

The robot 3 transports the FOUP 20 to each unit in the state of gripping the flange 20c of the FOUP 20. The robot 3 is, for example, a vertically articulated robot, and includes a robot arm 3a and a robot hand 3b. The robot 3 transports the FOUP 20 to each unit by, for example, extending or pivotably moving the robot arm 3a in the state where the flange 20c is gripped on the robot hand 3b.

The disassembly/connection stage 4 is used to disassemble the FOUP 20 into the body 20a and the door 20b, or connect (combine) the body 20a and the door 20b. A latch key 4a is provided on the disassembly/connection stage 4. By rotating the latch key 4a in the state of being inserted into a latch hole provided in the door 20b of the FOUP 20, the disassembly/connection stage 4 may disassemble (separate) the door 20b from the body 20a of the FOUP 20, or connect the door 20b to the body 20a.

The cleaning chamber 5 is a chamber for cleaning the FOUP 20. Details of the cleaning chamber 5 are described herein later.

In the unload port 6, the FOUP 20 disposed on the portion of the unload port 6 inside the casing 1a by the robot 3 is moved in the direction indicated by the arrow 6b and carried out of the casing 1a. The FOUP 20 is transported to the unload port 6 from the disassembly/connection stage 4 by the robot 3. The FOUP 20 corresponds to the FOUP 20 in the state where the door 20b is connected to the body 20a, on the disassembly/connection stage 4. Further, a shutter 6a provided in the opening 1c of the casing 1a is opened when the FOUP 20 is carried out, and closed when the FOUP 20 is not carried out.

The control unit 7 controls the operation of the entire wafer storage container cleaning apparatus 1. For example, the control unit 7 controls the load port 2, the robot 3, the disassembly/connection stage 4, the cleaning chamber 5, and the unload port 6, to operate the load port 2, the robot 3, the disassembly/connection stage 4, the cleaning chamber 5, and the unload port 6 as described above.

For example, the control unit 7 includes a central processing unit (CPU), a read only memory (ROM), a random access memory (RAM), a hard disk drive (HDD), and a communication interface. These components are connected to each other via an internal bus.

The CPU executes various processes while using the memory area of the RAM as a temporary storage area for data used in the various processes. The ROM and the HDD store, for example, programs for executing the various processes, or various databases and tables used when executing the various processes.

The communication interface communicates with each unit of the wafer storage container cleaning apparatus 1 described above, and also communicates with an external device connected to the wafer storage container cleaning apparatus 1 via a network. For example, the communication interface is a network interface card.

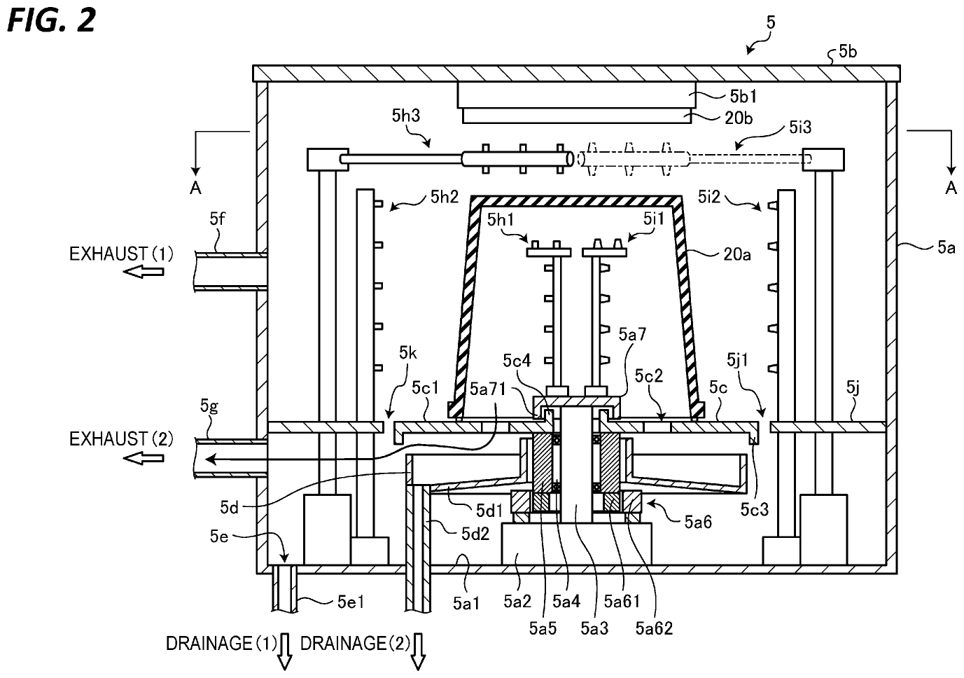

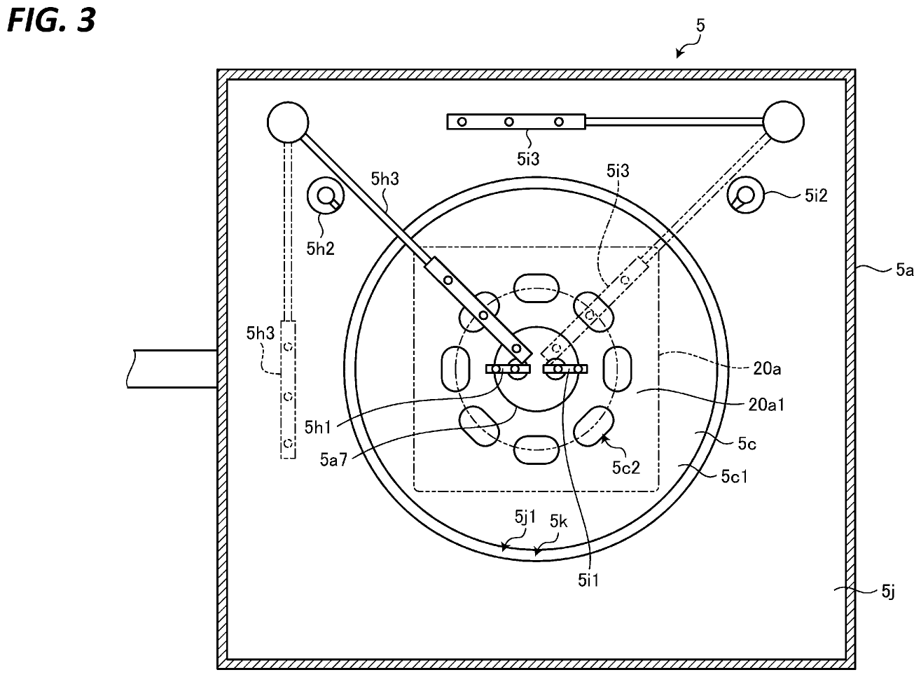

Next, the cleaning chamber 5 according to an embodiment is described. FIGS. 2 and 3 are views illustrating an example of the configuration of the cleaning chamber 5 according to an embodiment. Further, FIG. 3 is a cross-sectional view taken along the line A-A in FIG. 2, and illustrates the body 20a hidden in the state of being disposed in a placement unit 5c, in a double-dot dashed line. As illustrated in FIG. 2, for example, the cleaning chamber 5 includes a cleaning chamber body 5a, a lid unit 5b, the placement unit 5c, a first drainage receiving unit 5d, a second drainage receiving unit 5e, a first exhaust pipe 5f, a second exhaust pipe 5g, a plurality of cleaning liquid nozzles 5h1, 5h2, and 5h3, and a plurality of hot blow nozzles 5i1, 5i2, and 5i3.

The lid unit 5b is attached to the upper end of the cleaning chamber body 5a via a hinge, and opened/closed with respect to the body opening of the cleaning chamber body 5a by the driving of an air cylinder. On the back surface of the lid unit 5b (the surface on the side of the cleaning chamber body 5a), a holding unit (holding mechanism) 5b1 is provided to hold the door 20b of the FOUP 20.

The cleaning chamber body 5a is a box-shaped member that is opened at the top thereof, includes an opening (body opening) at the top thereof, and has a cleaning space that communicates with the body opening. The cleaning space is the space present in the inner side than the body opening. The body 20a is carried into the cleaning space through the body opening by the robot 3. In this way, the body 20a is carried into the cleaning chamber body 5a. Then, the cleaning chamber body 5a accommodates the body 20a.

In the present embodiment, when the cleaning of the FOUP 20 is performed in the cleaning chamber 5, the robot 3 transports the body 20a and the door 20b on the disassembly/connection stage 4, separately, to the cleaning chamber 5. For example, the robot 3 transports the body 20a from the opening of the cleaning chamber body 5a to the inside of the cleaning chamber body 5a in the state where the opening of the body 20a faces downward. Thus, the body 20a is disposed on the placement unit 5c in the state where the opening of the body 20a faces downward. Further, the robot 3 transports the door 20b to the holding unit 5b1 such that the outer surface of the door 20b is held by the holding unit 5b1 of the lid unit 5b. Thus, when the lid unit 5b is closed, the inner surface (interior side) of the door 20b faces downward.

When the cleaning of the FOUP 20 in the cleaning chamber 5 is complete, the robot 3 transports the body 20a and the door 20b in the cleaning chamber 5, separately, to the disassembly/connection stage 4. Then, the disassembly/connection stage 4 connects the body 20a and the door 20b to each other.

The placement unit 5c is provided at the center of the cleaning space of the cleaning chamber body 5a. The placement unit 5c is an example of a stage. The carried-in body 20a is disposed on the placement unit 5c. For example, as illustrated in FIG. 2, the placement unit 5c has a placement surface 5cl on which the body 20a is disposed in the state where the opening of the body 20a faces downward. In this way, the placement surface 5c supports the body 20a. The placement unit 5c is a disk-shaped member, and is rotatable. That is, a base unit 5a2 having a circular shape in plan view is provided at the bottom 5a1 of the cleaning chamber body 5a, and a supporting shaft 5a3 stands on the center of the base unit 5a2. The placement unit 5c is disposed on the upper end of a rotating member (rotating shaft) 5a5 provided via a shaft support 5a4 such as a bearing with respect to the supporting shaft 5a3.

The rotating member 5a5 is rotatably movable by a hollow motor 5a6. The hollow motor 5a6 includes a rotor 5a61 fixed to the lower end of the rotating member 5a5, and a stator 5a62 provided on the base unit 5a2 to correspond to the rotor 5a61. With this configuration, the placement unit 5c is rotatable by the driving of the hollow motor 5a6. As described above, the placement unit 5c has the circular shape in plan view, and is supported to be rotatable around the rotating member 5a5 provided at the center thereof.

In a region 20a1 in which the body 20a of the FOUP 20 is disposed (the region surrounded by the double-dot dashed line indicated by the reference numeral 20a in FIG. 3), the placement unit 5c includes a plurality of holes (apertures) 5c2 (eight holes in the illustrated example) arranged concentrically near the middle between the outer periphery of a support 5a7 to be described herein later and the outer periphery of the region 20a1. The holes 5c2 are provided to allow a drainage, which is a cleaning liquid after cleaning the inner side of the body 20a of the FOUP 20, and a gas inside the body 20a (gas inside the storage space of the body 20a) to flow beneath the placement unit 5c. Further, the eight holes 5c2 are set in size to have a sufficient aperture area to perform the exhaust. The size of the holes 5c2 is determined through, for example, experiments or simulation. However, as long as the required opening area is obtained, the plurality of holes 51c may not necessarily be arranged concentrically, and the number of holes 5c2 may not be limited. The plurality of holes 5c2 may be randomly arranged, or a single hole 5c2 may be provided.

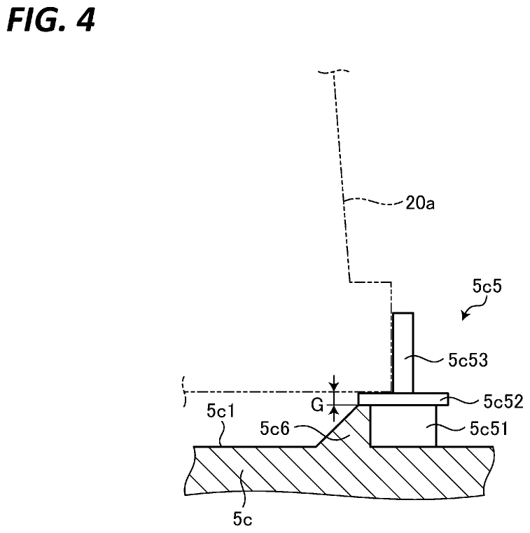

Further, the placement unit 5c includes support members 5c5 that support the body 20a (see, e.g., FIG. 4), and two support members 5c5 are provided for each corner of the body 20a such that each of the four corners of the body 20a is fitted in the support members 5c5 to align with the placement position of the body 20a indicated by the double-dot dashed line in FIG. 3. As illustrated in FIG. 4, each support member 5c5 includes a pedestal 5c51, a support portion 5c52 on which the outer peripheral edge of the opening of the body 20a is disposed, and a position regulation portion (pin-shaped member) 5c53 standing upright from the support portion 5c52 while being in contact with the side wall of the outer periphery of the opening of the body 20a, thereby regulating the position of the body 20a. With this configuration, the support member 5c5 may perform the positioning of the body 20a disposed on the placement unit 5c.

As illustrated in FIG. 4, in the placement unit 5c, a rectangularly annular raised ridge 5c6 is provided at a position of a slightly inward side from the outer peripheral edge of the body 20a to follow the outer peripheral edge of the body 20a to be disposed. The raised ridge 5c6 is formed such that its cross section orthogonal to the perimeter direction has a trapezoidal shape with the vertical lateral surface on the outer peripheral side and the shorter upper side than the lower side. Further, the raised ridge 5c6 is formed such that the height thereof is the same as the height of the pedestal 5c51 of the support member 5c5, and the lower surface of the support portion 5c52 is in contact with the upper surface of the raised ridge 5c6. Accordingly, as indicated two arrows, a gap G is formed between the body 20a and the raised ridge 5c6 of the placement unit 5c, except for the portion of the body 20a supported on the support portion 5c52. This is because, when the body 20a is dried in the cleaning chamber 5, the body 20a may be more effectively dried when the gap G is formed between the body 20a and the raised ridge 5c6 of the placement unit 5c, as compared to the case where no gap is formed between the body 20a and the raised ridge 5c6 of the placement unit 5c. In the case where the body 20a is in contact with the raised ridge 5c6 of the placement unit 5c without forming a gap, the cleaning liquid entering between the body 20a and the upper surface of the raised ridge 5c6, that is, between the contact surfaces of both the body 20a and the raised ridge 5c6 is concealed by the body 20a and the raised ridge 5c6, and therefore, is hard to be dried. Further, the cleaning liquid remaining on the inner side of the raised ridge 5c6 may be discharged relying only on the holes 5c2, which may impair the efficiency of drying. Meanwhile, when the gap G is formed between the body 20a and the raised ridge 5c6 as described above, the cleaning liquid adhering to the body 20a at the position of the gap G may be effectively removed. Further, it may be expected that the cleaning liquid remaining on the inner side of the raised ridge 5c6 is also discharged through the gap between the body 20a and the raised ridge 5c6 by the centrifugal force generated from the rotation of the placement unit 5c, and as a result, the removability of the cleaning liquid may be improved. FIG. 4 is a view illustrating an example of the configuration of the support member 5c5 according to an embodiment.

The placement unit 5c includes a circularly annular raised ridge 5c3 extending downwardly along the outer peripheral end thereof. Further, a first drainage receiving unit 5d is provided below the placement unit 5c to receive the drainage discharged from the holes 5c2 of the placement unit 5c (the cleaning liquid after cleaning the inner side of the body 20a).

The first drainage receiving unit 5d makes up a circularly annular recess surrounding the rotating member 5a5 supporting the placement unit 5c, and is disposed via a supporting column (not illustrated) on the bottom 5a1 of the cleaning chamber body 5a. Thus, the first drainage receiving unit 5d has the shape of a circularly annular recess in plan view. The first drainage receiving unit 5d is provided such that the outer shape thereof is slightly smaller than the outer shape of the placement unit 5c (the inner diameter of the circularly annular raised ridge 5c3). Further, the first drainage receiving unit 5d is provided, forming a height difference between the upper end of the outer periphery of the first drainage receiving unit 5d and the lower end of the raised ridge 5c3 of the outer peripheral end of the placement unit 5c to the extent that the exhaust from the holes 5c2 of the placement unit 5c may flow sufficiently. The bottom 5d1 of the recess portion of the first drainage receiving unit 5d (recess bottom) is configured with a sloped surface that gradually descends from the center side toward the outer peripheral side. Further, a drainage pipe 5d2 is connected to the outer peripheral end of the lowermost portion of the recess bottom 5d1 to discharge the received drainage to the outside. FIG. 2 illustrates an example where a single drainage pipe 5d2 is provided, but two or more drainage pipes 5d2 may be provided. The first drainage receiving unit 5d and the drainage pipe 5d2 may be collectively referred to as a first drainage receiving unit. That is, the drainage pipe 5d2 may be included as a component of the first drainage receiving unit 5d. FIG. 2 illustrates Drainage (2) as the drainage discharged to the outside by the first drainage receiving unit 5d.

The first drainage receiving unit 5d is disposed such that the inner peripheral end of the first drainage receiving unit 5d is positioned between the holes 5c2 formed in the placement unit 5c and the rotating member 5a5, and the outer peripheral end of the first drainage receiving unit 5d is positioned between the outermost periphery of the body 20a disposed on the placement surface 5cl in the state where the opening of the body 20a faces downward, and the outer peripheral end of the placement unit 5c. Further, the first drainage receiving unit 5d is disposed such that a gap is formed between the outer periphery of the first drainage receiving unit 5d and the placement unit 5c, to allow the flow of the gas flowing from the storage space of the body 20a toward the second exhaust pipe 5g through the holes 5c2.

On the outer peripheral side of the placement unit 5c, a partition plate 5j is provided, forming a circular opening 5j1 surrounding the placement unit 5c (an opening with an inner diameter slightly larger than the outer shape of the placement unit), and abutting the inner wall surface of the cleaning chamber body 5a at the outer periphery thereof. The partition plate 5j is disposed such that the upper surface thereof is flush with the upper surface of the placement unit 5c. The partition plate 5j divides the inside of the cleaning chamber body 5a into an upper space above the placement unit 5c and a lower space below the placement unit 5c. Specifically, the partition plate 5j divides the cleaning space in the cleaning chamber body 5a into an upper cleaning space above the placement unit 5c and a lower cleaning space below the placement unit 5c. Here, the holes 5c2 described above communicate the upper cleaning space and the lower cleaning space with each other.

The partition plate 5j has a gap 5k between the opening 5j1 and the outer periphery of the placement unit 5c. The gap 5k serves as a drainage passage that allows the drainage, which is the cleaning liquid after cleaning the outer side of the body 20a of the FOUP 20, to flow into the lower space below the partition plate 5j (the bottom 5a1 of the cleaning chamber body 5a). Here, as described herein later, in the present embodiment, the upper space and the lower space are exhausted separately. Thus, the gap 5k may be formed in a small size. Therefore, in the present embodiment, the placement unit 5c has the disk shape, and the circular opening 5j1 is formed in the partition plate 5j to conform to the shape of the placement unit 5c. As a result, the size of the gap 5k may be reduced, as compared to the case where the shape of the placement unit 5c and the shape of the opening formed in the partition plate 5j are a polygonal shape such as square.

In the lower space below the partition plate 5j, a second drainage receiving unit 5e is provided. The second drainage receiving unit 5e is made up by the bottom 5a1 of the cleaning chamber body 5a and a drainage pipe 5e1. That is, the second drainage receiving unit 5e includes the bottom 5a1 and the drainage pipe 5e1. The bottom 5a1 mainly receives the drainage, which is the cleaning liquid after cleaning the outer side of the body 20a of the FOUP 20. Further, the drainage pipe 5e1 is provided in the bottom 5a1. The drainage pipe 5e 1 discharges the drainage received by the bottom 5a1 to the outside. FIG. 2 illustrates Drainage (1) as the drainage discharged to the outside by the second drainage receiving unit 5e. FIG. 2 illustrates a single drainage pipe 5e1, but two or more drainage pipes 5e 1 may be provided.

Two exhaust pipes (a first exhaust pipe 5f and a second exhaust pipe 5g) are connected to the side wall of the cleaning chamber body 5a, to exhaust the inside of the cleaning chamber body 5a. The first exhaust pipe 5f is connected to the side wall above the partition plate 5j, and mainly exhausts the upper space above the partition plate 5j and the placement unit 5c. Through the exhaust, water vapor generated from the cleaning of the outer side of the body 20a of the FOUP 20 is exhausted. FIG. 2 illustrates Exhaust (1) as the exhaust by the first exhaust pipe 5f. Further, the first exhaust pipe 5f is connected to an adjustment device that adjusts the exhaust volume of a pump or the like (not illustrated), and the exhaust volume is adjusted by the device. Here, the “water vapor” is not limited to vaporized steam of water or the cleaning liquid, but encompasses comprehensively particles that are generated from the cleaning, and undesirably adhere to the FOUP 20 while drifting in the space, such as mist of water or the cleaning liquid, and mist including particles.

The second exhaust pipe 5g is connected to the side wall below the partition plate 5j, and mainly exhausts the lower space below the partition plate 5j and the placement unit 5c. Through the exhaust, water vapor generated from the cleaning of the inner side of the body 20a of the FOUP 20 is exhausted. In the present embodiment, the second exhaust pipe 5g is configured to exhaust the lower space below the partition plate 5j and the placement unit 5c, thereby exhausting at least the storage space made up by the inner side of the body 20a. FIG. 2 illustrates Exhaust (2) as the exhaust by the second exhaust pipe 5g. Further, the second exhaust pipe 5g is connected to an adjustment device that adjusts the exhaust volume of a pump or the like (not illustrated), and the exhaust volume is adjusted by the device.

The exhaust volume when the exhaust by the first exhaust pipe 5f is performed and the exhaust volume when the exhaust by the second exhaust pipe 5g is performed may be adjusted such that the lower space (the space on the draining side) has a negative pressure with respect to the upper space (the space on the cleaning side). This is because, when the upper space has a negative pressure, water vapor in the lower space may invade the upper space, and adhere to the outer side of the body 20a of the FOUP 20. Meanwhile, when the pressure difference is excessively large, water vapor outside the body 20a of the FOUP 20 may be drawn into the inside of the body 20a from the gap between the body 20a of the FOUP 20 and the placement unit 5c. Therefore, it is desirable to maintain the pressure difference to the extent that the water vapor on the draining side does not leak into the space on the cleaning side from the gap 5k between the placement unit 5c and the partition plate 5j.

The first exhaust pipe 5f, the adjustment device connected to the first exhaust pipe 5f, the second exhaust pipe 5g, and the adjustment device connected to the second exhaust pipe 5g are an example of an exhaust unit.

The supporting shaft 5a3 on the base unit 5a2 is provided such that the upper end thereof protrudes above the placement unit 5c. A support 5a7 having a circular shape in plan view is provided on the upper end of the supporting shaft 5a3. The outer peripheral portion of the support 5a7 overlaps with the inner peripheral portion of the placement unit 5c, while being spaced apart from each other vertically. Further, a circularly annular raised ridge 5a71 is provided to extend downwardly at the outer peripheral end of the support 5a7. A small gap is formed between the lower end of the raised ridge 5a71 and the upper surface of the placement unit 5c (the placement surface 5c1). A circularly annular raised ridge 5c4 is provided to extend upwardly at the inner peripheral end of the placement unit 5c, while forming a small gap between the raised ridge 5c4 and the inner side of the raised ridge 5a71 of the support 5a7. A small gap is also formed between the raised ridge 5c4 of the placement unit 5c and the lower surface of the support 5a7. As a result, a labyrinth seal is constructed between the placement unit 5c and the support 5a7. Thus, water vapor generated by cleaning the inner side of the body 20a of the FOUP 20 may be suppressed from entering the inside of the rotating member 5a5 and the hollow motor 5a6 through the gap between the placement unit 5c and the support 5a7.

On the upper surface of the support 5a7, a cleaning liquid nozzle 5h1 for cleaning the inner side of the body 20a of the FOUP 20 and a hot blow nozzle 5i1 for blowing away, evaporating, and removing droplets of a residual cleaning liquid adhering to the inner side of the body 20a after the cleaning are provided in a standing posture. A supply pipe for supplying the cleaning liquid to the cleaning liquid nozzle 5h1 and a supply pipe for supplying the hot blow to the hot blow nozzle 5i1 are connected in the supporting shaft 5a3, passing through the supporting shaft 5a3.

The cleaning liquid nozzle 5h1 is provided in a position at which the cleaning liquid may be supplied to the inner side (storage space) of the body 20a disposed on the placement unit 5c. For example, the cleaning liquid nozzle 5h1 includes at least one rod-shaped pipe extending upwardly from the support 5a7, at least one rod-shaped pipe extending horizontally from the top of the upwardly extending pipe, and a plurality of nozzles provided on each pipe. The nozzle is, for example, a two-fluid nozzle. When the nozzle is a two-fluid nozzle, the nozzle cleans the inner side of the body 20a by mixing air (example of a gas) with the cleaning liquid to atomize the cleaning liquid using the flow of air, and supplying the atomized cleaning liquid to the inner side of the body 20a. Alternatively, the nozzle may supply the cleaning liquid to the inner side of the body 20a without mixing air and the cleaning liquid. That is, the nozzle may supply the cleaning liquid to the inner side of the body 20a without atomizing the cleaning liquid.

The hot blow nozzle 5i1 is provided in a position at which hot blow (hot air (heated gas)) may be supplied to the inner side of the body 20a disposed on the placement unit 5c. For example, the hot blow nozzle 5i1 includes at least one rod-shaped pipe extending upwardly from the support 5a7, at least one rod-shaped pipe extending horizontally from the top of the upwardly extending pipe, and a plurality of nozzles provided on each pipe. The nozzle dries the inner side of the body 20a disposed on the placement unit 5c by supplying the hot blow to the inner side of the body 20a.

On the outer side of the placement unit 5c, cleaning liquid nozzles 5h2 and 5h3 are provided to clean the outer side of the body 20a of the FOUP 20, and hot blow nozzles 5i2 and 5i3 are provided to blow away, evaporate, and remove droplets of the residual cleaning liquid adhering to the outer side of the body 20a after the cleaning.

The cleaning liquid nozzle 5h2 supplies the cleaning liquid to the body 20a of the FOUP 20 from the lateral side (outer side). As illustrated in FIG. 3, the cleaning liquid nozzle 5h2 is provided to stand vertically upright which passing through the partition plate 5j from the bottom 5a1 of the cleaning chamber body 5a, near one corner of the cleaning chamber body 5a (the upper left corner in FIG. 3). For example, the cleaning liquid nozzle 5h2 includes at least one rod-shaped pipe extending upwardly from the bottom 5a1, and a plurality of nozzles provided in the pipe. The nozzle is, for example, a two-fluid nozzle. For example, the nozzle cleans the lateral side of the body 20a by supplying the atomized cleaning liquid to the lateral side of the body 20a. Alternatively, the nozzle may supply the cleaning liquid to the lateral side of the body 20a without atomizing the cleaning liquid.

The cleaning liquid nozzle 5h3 supplies the cleaning liquid to the body 20a of the FOUP 20 from above (outer side). The cleaning liquid nozzle 5h3 is provided to pivot between a standby position indicated by a double-dot dashed line and a cleaning position indicated by a solid line in FIG. 3. In FIG. 2, the cleaning liquid nozzle 5h3 indicated by a solid line is located at the cleaning position. More specifically, the cleaning liquid nozzle 5h3 includes a pivoting pillar provided to stand vertically upright (higher than the cleaning liquid nozzle 5h2) while passing though the partition plate 5j from the bottom 5a1 of the cleaning chamber body 5a, at a position closer to the corner of the cleaning chamber body 5a than the cleaning liquid nozzle 5h2 is, a pivoting arm extending horizontally while being fixed to the top of the pillar, and a nozzle unit provided on the tip end of the pivoting arm to extend horizontally. The nozzle unit is provided with one or more nozzles. The nozzle is, for example, a two-fluid nozzle. For example, the nozzle cleans the upper side of the body 20a by supplying the atomized cleaning liquid to the upper side of the body 20a in the pivoting state. Alternatively, the nozzle may supply the cleaning liquid to the upper side of the body 20a without atomizing the cleaning liquid.

The hot blow nozzle 5i2 supplies the hot blow to the body 20a of the FOUP 20 from the lateral side (outer side). As illustrated in FIG. 3, the hot blow nozzle 5i2 is provided to stand vertically upright while passing through the partition plate 5j from the bottom 5a1 of the cleaning chamber body 5a, near one corner of the cleaning chamber body 5a (the upper right corner in FIG. 3). For example, the cleaning liquid nozzle 5i2 includes at least one rod-shaped pipe extending upwardly from the bottom 5a1, and a plurality of nozzles provided in the pipe. The nozzle dries the lateral side (outer side) of the body 20a disposed in the placement unit 5c by supplying the hot blow to the lateral side (outer side) of the body 20a.

The hot blow nozzle 5i3 supplies the hot blow to the body 20a of the FOUP 20 from above. The hot blow nozzle 5i3 is provided to pivot between a drying position indicated by a double-dot dashed line and a standby position indicated by a solid line in FIG. 3. In FIG. 2, the hot blow nozzle 5i3 indicated by a double-dot dashed line is located at the drying position. More specifically, the hot blow nozzle 5i3 includes a pivoting pillar provided to stand vertically upright (higher than the hot blow nozzle 5i2) while passing through the partition plate 5j from the bottom 5a1 of the cleaning chamber body 5a, at a position closer to the corner of the cleaning chamber body 5a than the hot blow nozzle 5i2 is, a pivoting arm extending horizontally while being fixed to the top of the pillar, and a nozzle unit provided at the tip end of the pivoting arm to extend horizontally. The nozzle unit is provided with one or more nozzles. The nozzle dries the upper side (outer side) of the body 20a disposed in the placement unit 5c by supplying the hot blow to the upper side (outer side) of the body 20a at the drying position. FIG. 2 omits the illustration of the hot blow nozzle 5i3 located at the standby position indicated by the solid line in FIG. 3.

The cleaning liquid nozzle 5h3 waits in the standby position that does not interfere with the body 20a as indicated by the double-dot dashed line in FIG. 3, when the body 20a is carried in/out and dried. Then, after the body 20a is carried into the cleaning space of the cleaning chamber body 5a, and the lid unit 5b is closed in the state where the door 20b is held by the holding unit 5b1, the cleaning liquid nozzle 5h3 pivots and moves to the cleaning position above the body 20a disposed on the placement unit 5c and below the door 20b held by the holding unit 5b1 (the position indicated by the solid line). When the cleaning is completed, the cleaning liquid nozzle 5h3 pivots and moves to the standby position.

Further, for example, the hot blow nozzle 5i3 waits in the standby position that does not interfere with the body 20a as indicated by the solid line in FIG. 3, when the body 20a is carried in/out and cleaned. Then, when the cleaning is terminated, the hot blow nozzle 5i3 pivots and moves to the drying position above the body 20a disposed on the placement unit 5c and below the door 20b held by the holding unit 5b1. When the drying is completed, the hot blow nozzle 5i3 pivots and moves to the standby position.

The cleaning liquid nozzles 5h1, 5h2, and 5h3 are an example of a cleaning liquid supply unit. Further, the hot blow nozzles 5i1, 5i2, and 5i3 are an example of a heated gas supply unit.

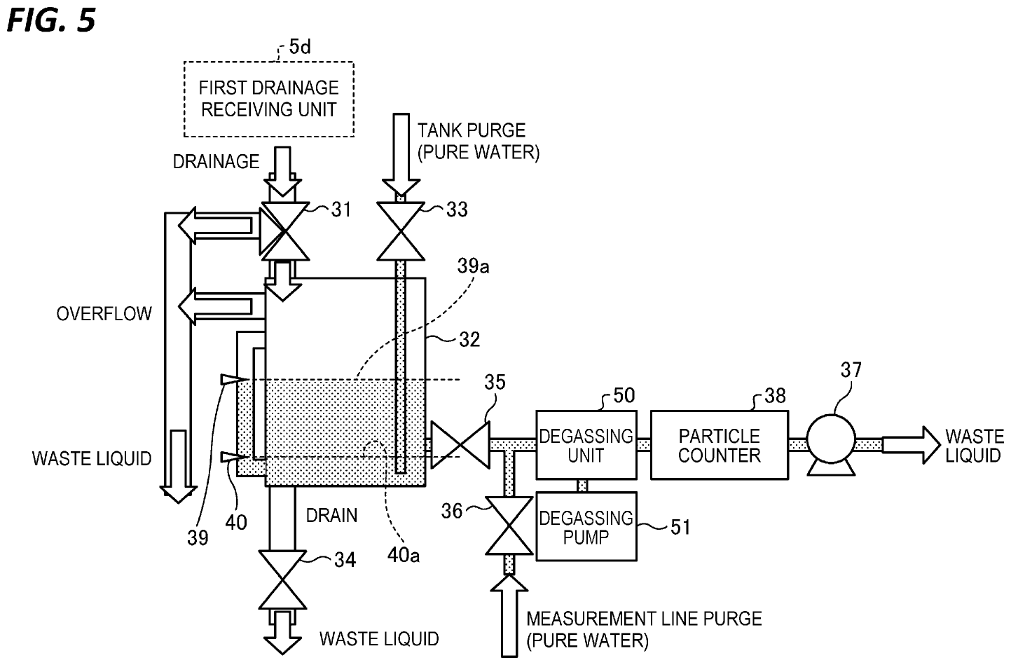

Next, descriptions are made on an example of a configuration of each unit provided in a flow path through which a drainage (Drainage 2) flows, at a further rear end than the first drainage receiving unit 5d of the wafer storage container cleaning apparatus 1. FIG. 5 is a view illustrating an example of the configuration of each unit provided in the flow path in which a drainage flows, at a further rear end than the first drainage receiving unit, according to an embodiment. Here, it is assumed that the components making up the first drainage receiving unit 5d includes the drainage pipe 5d2.

As illustrated in FIG. 5, in the flow path through which a drainage flows at the further rear end than the first drainage receiving unit 5d, a three-way valve 31, a drainage measurement tank 32, AO valves (air operation valves) 33 to 36, a pump 37, a particle counter 38, liquid level sensors 39 and 40, a degassing unit 50, and a degassing pump 51 are provided. In the descriptions herein below, the AO valve 33 may be referred to as a first AO valve 33, the AO valve 34 may be referred to as a second AO valve 34, the AO valve 35 may be referred to as a third AO valve 35, and the AO valve 36 may be referred to as a fourth AO valve 36.

The three connection ports of the three-way valve 31 are connected to the first drainage receiving unit 5d, the waste liquid side (the left side in FIG. 5), and the drainage measurement tank 32. For example, the drainage discharged by the first drainage receiving unit 5d is introduced into the three-way valve 31. Then, the three-way valve 31 is controlled by the control unit 7, and the drainage introduced into the three-way valve 31 is discharged to either one of the waste liquid side and the drainage measurement tank 32.

In the drainage measurement tank 32, drainage including particles that are measured by the particle counter 38 is collected.

The first AO valve 33 is provided in a flow path through which pure water flows toward the drainage measurement tank 32. When the first AO valve 33 is opened, the pure water is supplied to the drainage measurement tank 32. When the first AO valve 33 is closed, the supply of pure water to the drainage measurement tank 32 stops.

The second AO valve 34 is provided in a flow path through which a drainage from the drainage measurement tank 32 flows as a waste liquid. When the second AO valve 34 is opened, the waste liquid flows out of the drainage measurement tank 32. When the second AO valve 34 is closed, the outflow of waste liquid from the drainage measurement tank 32 stops.

The third AO valve 35 is provided in a flow path through which a drainage flows from the drainage measurement tank 32 toward the particle counter 38 via the degassing unit 50. When the third AO valve 35 is opened, the drainage from the drainage measurement tank 32 is supplied to the particle counter 38. When the third AO valve 35 is closed, the supply of drainage to the particle counter 38 stops.

The fourth AO valve 36 is provided in a flow path through which pure water flows toward the particle counter 38 via the degassing unit 50. When the fourth AO valve 36 is opened, the pure water is supplied to the particle counter 38 and the flow path thereof (measurement line). When the fourth AO valve 36 is closed, the supply of pure water to the particle counter 38 and the flow path (measurement line) thereof stops.

The pump 37 operates to draw the drainage or pure water thereinto. The drainage drawn by the pump 37 is discharged as a waste liquid.

The particle counter 38 measures the particles included in the supplied drainage, and outputs information about the particles. For example, the particle counter 38 measures the number of particles included in a predetermined unit volume of drainage (e.g., 10 ml). Then, the particle counter 38 outputs the number of particles included in the predetermined unit volume of drainage to the control unit 7 as information about the particles. The particle counter 38 is an example of a particle measurement unit.

The liquid level sensor 39 is provided at a position defining an upper limit of the drainage collected in the drainage measurement tank 32, and detects whether the height of the liquid level of the drainage collected in the drainage measurement tank 32 has reached a height 39a equal to the height of the liquid level sensor 39. The liquid level sensor 39 performs the detection at predetermined time intervals. Then, the liquid level sensor 39 outputs the detection result to the control unit 7 at predetermined time intervals.

The liquid level sensor 40 is provided at a position defining a lower limit of the drainage collected in the drainage measurement tank 32, and detects whether the height of the liquid level of the drainage collected in the drainage measurement tank 32 has reached a height 40a equal to the height of the liquid level sensor 40. The liquid level sensor 40 performs the detection at predetermined time intervals. Then, the liquid level sensor 40 outputs the detection result to the control unit 7 at predetermined time intervals.

The degassing unit 50 and the degassing pump 51 are provided in the front of the particle counter 38, and degas the drainage supplied to the particle counter 38. Further, the degassing unit 50 and the degassing pump 51 do not degas the pure water supplied to the particle counter 38.

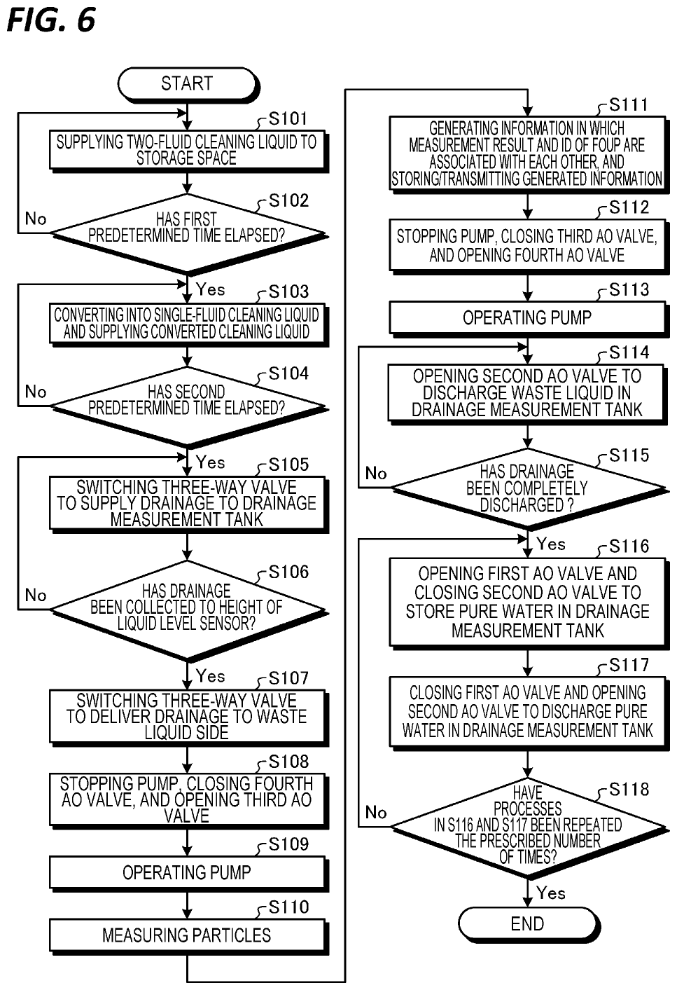

Next, an example of the process performed by the wafer storage container cleaning apparatus 1 is described. FIG. 6 is a flowchart illustrating an example of the flow of the process performed by the wafer storage container cleaning apparatus 1 (operation of the wafer storage container cleaning apparatus 1) according to an embodiment. The process illustrated in FIG. 6 is performed when the cleaning of the FOUP 20 is performed in the cleaning chamber 5. Further, for example, the process illustrated in FIG. 6 is performed by each unit other than the control unit 7 under the control from the control unit 7.

When the body 20a and the door 20b are carried into the cleaning space, the cleaning chamber 5 starts the cleaning. At this time, first, the cleaning liquid nozzle 5h3 moves from the standby position to the cleaning position. The placement unit 5c starts to rotate. At a timing when the cleaning liquid nozzle 5h3 is located at the cleaning position, and the placement unit 5c reaches a preset rotation speed, the cleaning liquid nozzles 5h1, 5h2, and 5h3 start supplying, for example, the atomized cleaning liquid (two fluids) to the inner side and the outer side of the body 20a (step S101). At this time, the three-way valve 31 discharges the drainage from the first drainage receiving unit 5d to the waste liquid side.

Next, the control unit 7 determines whether a first predetermined time has elapsed from the start of the cleaning of the FOUP 20 (the start of supply of the cleaning liquid in the two-fluid form (two-fluid cleaning liquid)) (step S102).

When it is determined that the first predetermined time has not elapsed from the start of the cleaning of the FOUP 20 (step S102: No), the supply of the cleaning liquid is continued, and the control unit 7 performs the determination of step S102 again. Meanwhile, when it is determined that the first predetermined time has elapsed from the start of the cleaning of the FOUP 20 (step S102: Yes), the cleaning liquid nozzles 5h1, 5h2, and 5h3 start supplying the cleaning liquid that is not mixed with air, and thus, is not atomized (pure water), to the inner side and the outer side of the body 20a (step S103). That is, in step S103, the cleaning liquid nozzles 5h1, 5h2, and 5h3 convert the fluid ejected from the cleaning fluid nozzles 5h1, 5h2, and 5h3 from the two fluids of air and the cleaning liquid to pure water (single fluid).

Next, the control unit 7 determines whether a second predetermined time has elapsed after the conversion to pure water in step S103 (step S104). The second predetermined time is, for example, a time during which the two-fluid cleaning liquid in the storage space is completely discharged from the storage space by the supply of pure water.

When it is determined that the second predetermined time has not elapsed after the conversion to pure water (step S104: No), the supply of the cleaning liquid in the single fluid form (single-fluid cleaning liquid) is continued, and the control unit 7 performs the determination of step S104 again. Meanwhile, when it is determined that the second predetermined time has elapsed after the conversion to pure water (step S104: Yes), the control unit 7 switches the three-way valve 31 such that the drainage introduced into the three-way valve 31 (the pure water that is the single-fluid cleaning liquid) flows out to the drainage measurement tank 32 (step S105). That is, the control unit 7 controls the three-way valve 31 such that the drainage flows out to the drainage measurement tank 32. At this time, the first AO valve 33, the second AO valve 34, and the third AO valve 35 are in the closed state, and the fourth AO valve 36 is in the opened state. Further, the pump 37 starts to operate at the timing when the two-fluid cleaning liquid is supplied to the inner side (storage space) of the body 20a in step S101, so that the pure water is being supplied to the particle counter 38. This is a process for keeping the particle measurement area clean before starting the measurement by the particle counter 38.

Then, the control unit 7 determines whether the drainage has been collected in the drainage measurement tank 32 to the height 39a equal to the height of the liquid level sensor 39, based on the detection result output from the liquid level sensor 39 at the predetermined time intervals (step S106).

When it is determined that the drainage has not been collected to the height 39a equal to the height of the liquid level sensor 39 (step S106: No), the control unit 7 continues the outflow of the drainage to the drainage measurement tank 32, and performs the determination of step S106 again. Meanwhile, when it is determined that the drainage has been collected to the height 39a equal to the height of the liquid level sensor 39 (step S106: Yes), the control unit 7 switches the three-way valve 31 such that the drainage introduced into the three-way valve 31 flows out to the waste liquid side (step S107). That is, the control unit 7 controls the three-way valve 31 such that the drainage flows out to the waste liquid side.

Subsequently, the control unit 7 stops the pump 37, closes the fourth AO valve 36, and opens the third AO valve 35 (step S108).

Next, the control unit 7 operates the pump 37 to transfer the drainage in the drainage measurement tank 32 to the particle counter 38 (step S109).

Next, the particle counter 38 measures the number of particles included in the predetermined unit volume of drainage, and outputs the number of particles included in the predetermined unit volume of drainage to the control unit 7 as information about the particles (step S110).

Next, the control unit 7 generates information in which the measurement result and an ID (object identification number) of the FOUP 20 are associated with each other, stores the generated information in the HDD of the control unit 7, and controls the communication interface of the control unit 7 to output the information to an external device that collectively manages all FOUPs in the plant (step S111). For example, the control unit 7 includes an ID reading unit, and the ID reading unit reads the ID provided in the FOUP 20 as the identification information of the FOUP 20. For example, the ID of the FOUP 20 may be obtained by a barcode scanner (barcode reader), which is the ID reading unit. For example, the barcode scanner reads a barcode representing an object identification number of the FOUP 20 as the ID of the FOUP 20, and transmits the object identification number represented by the read barcode to the control unit 7. Further, for example, the ID reading unit may be a reader that reads the object identification number of the FOUP 20 output as the ID of the FOUP 20 from an RF tag provided in the FOUP 20. In this case, the reader transmits the read object identification number to the control unit 7. Further, instead of outputting the measurement result of the particles to the external device that collectively manages all FOUPs in the plant, the control unit 7 may store information of the measurement result in the RF tag provided in the FOUP 20.

By the process performed in step S111, the information about the particles measured by the particle counter 38 is output to the external device. Further, the HDD stores a history of information about the particles associated with the FOUP 20 (more specifically, the ID of the FOUP 20).

Next, the control unit 7 stops the pump 37, closes the third AO valve 35, and opens the fourth AO valve 36 (step S112).

Next, the control unit 7 operates the pump 37 to transfer the pure water to the particle counter 38 and the flow path thereof, thereby purging the flow path (step S113).

Next, the control unit 7 opens the second AO valve 34 to discharge the drainage remaining in the drainage measurement tank 32 as the waste liquid (step S114).

Next, the control unit 7 determines whether the drainage remaining in the drainage measurement tank 32 has been completely discharged from the drainage measurement tank 32 (step S115). For example, based on the detection result output from the liquid level sensor 40 at the predetermined time intervals, the control unit 7 determines that the drainage remaining in the drainage measurement tank 32 has been completely discharged from the drainage measurement tank 32, when a predetermined time has elapsed since the liquid level of the drainage reaches the height 40a equal to the height of the liquid level sensor 40. Otherwise, the control unit 7 determines that the drainage remaining in the drainage measurement tank 32 has not been completely discharged from the drainage measurement tank 32.

When it is determined that the drainage remaining in the drainage measurement tank 32 has not been completely discharged from the drainage measurement tank 32 (step S115: No), the control unit 7 continues to discharge the drainage, and performs the determination of step S115 again. Meanwhile, when it is determined that the drainage remaining in the drainage measurement tank 32 has been completely discharged from the drainage measurement tank 32 (step S115: Yes), the control unit 7 opens the first AO valve 33, and closes the second AO valve 34 (step S116). As a result, the pure water is supplied to the drainage measurement tank 32, and collected in the drainage measurement tank 32. In step S116, the drainage measurement tank 32 collects the pure water until the pure water overflows. Further, the time required until the pure water overflows may be calculated in advance, and the pure water may be continuously supplied to the drainage measurement tank 32 for the calculated time.

Subsequently, the control unit 7 closes the first AO valve 33, and opens the second AO valve 34 (step S117). As a result, the pure water in the drainage measurement tank 32 is discharged from the drainage measurement tank 32.

Next, the control unit 7 determines whether the processes in steps S116 and S117 have been repeated a predetermined number of times (step S118). When the processes in steps S116 and S117 are repeated the predetermined number of times, the inside of the drainage measurement tank 32 is purged.

When it is determined that the processes in steps S116 and S117 have not been repeated the predetermined number of times (step S118: No), the control unit 7 returns to step S116, and performs each process of step S116 and subsequent steps thereof again. Meanwhile, when it is determined that the processes in steps S116 and S117 have been repeated the predetermined number of times (step S118: Yes), the control unit 7 terminates the process illustrated in FIG. 6.

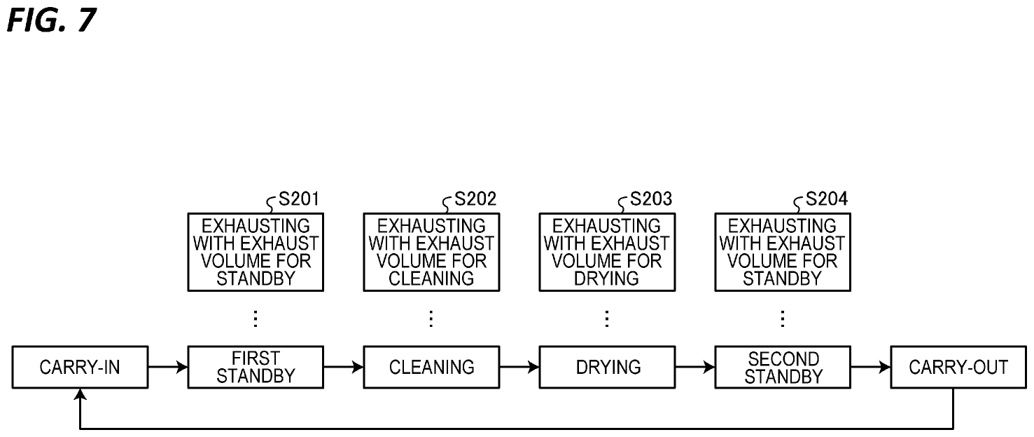

Next, an example of the exhaust performed by the wafer storage container cleaning apparatus 1 is described. FIG. 7 is a view illustrating an example of the exhaust performed by the wafer storage container cleaning apparatus 1 according to an embodiment. FIG. 7 illustrates not only the exhaust but also processes other than the exhaust performed by the wafer storage container cleaning apparatus 1.

In the present embodiment, the adjustment devices connected to the first exhaust pipe 5f and the second exhaust pipe 5g, respectively, are controlled to set different exhaust volumes in the process of carrying the body 20a and the door 20b of the FOUP 20 into or out of the cleaning chamber 5 (“carry-in” and “carry-out” in FIG. 7), the process of cleaning the body 20a and the door 20b carried into the cleaning chamber 5 (“cleaning” in FIG. 7), the process of drying the cleaned body 20a and door 20b (“drying” in FIG. 7), and the process until the cleaning starts after the body 20a and the door 20b are carried into the cleaning chamber 5 and the process until the dried body 20a and door 20b are carried out (“first standby” and “second standby” in FIG. 7).

First, in the carry-in process, the exhaust is performed neither in the first exhaust pipe 5f nor in the second exhaust pipe 5g. That is, the carry-in process corresponds to the time period after the lid unit 5b of the cleaning chamber 5 is opened to carry the body 20a and the door 20b of the FOUP 20 into the cleaning chamber 5, until the lid unit 5b of the cleaning chamber 5 is closed, and the wafer storage container cleaning apparatus 1 does not perform the exhaust during the time period.

The first standby process corresponds to the time period after the lid unit 5b of the cleaning chamber 5 is closed, until the cleaning of the body 20a and the door 20b of the FOUP 20 starts. During the first standby process, the wafer storage container cleaning apparatus 1 is exhausted with an exhaust volume for the first standby. Specifically, the adjustment device (not illustrated) of the first exhaust pipe 5f is controlled to exhaust the upper space above the partition plate 5j and the placement unit 5c with a first exhaust volume for the first standby. Further, the adjustment device (not illustrated) of the second exhaust pipe 5g is controlled to exhaust the lower space below the partition plate 5j and the placement unit 5c with a second exhaust volume for the first standby (step S201). Further, when the cleaning is started immediately after the carry-in process, the first standby process is omitted, and the cleaning process is performed.

The cleaning process corresponds to the time period after the cleaning of the body 20a and the door 20b of the FOUP 20 are started, until the cleaning is completed. In the cleaning process, the processes of steps S101 to S118 illustrated in FIG. 6 are performed. During the cleaning process, the wafer storage container cleaning apparatus 1 performs the exhaust with an exhaust volume for the cleaning. Specifically, the adjustment device (not illustrated) of the first exhaust pipe 5f is controlled to exhaust the upper space above the partition plate 5j and the placement unit 5c with a first exhaust volume for the cleaning. Further, the adjustment device (not illustrated) of the second exhaust pipe 5g is controlled to exhaust the lower space below the partition plate 5j and the placement unit 5c with a second exhaust volume for the cleaning (step S202). This exhaust performed by the first exhaust pipe 5f and the second exhaust pipe 5g during the cleaning is an example of a first exhaust. For example, the second exhaust pipe 5g performs the first exhaust to exhaust the storage space during the cleaning of the inner side of the body 20a by the cleaning liquid nozzle 5h1.

During the cleaning, the amount of water vapor generated in the cleaning chamber 5 increases relatively. Thus, the first exhaust volume for the cleaning is set to be larger than the first exhaust volume for the first standby. Similarly, the second exhaust volume for the cleaning is set to be larger than the second exhaust volume for the first standby.

The drying process corresponds to the time period from the start of the drying of the body 20a and the door 20b of the FOUP 20 until the drying is completed. In the drying process, for example, the hot blow is supplied to the inner side and the outer side of the body 20a from the hot blow nozzles 5i1, 5i2, and 5i3 for a predetermined time. During the drying, the body 20a and the door 20b are rotated. The rotation speed of the body 20a and the door 20b during the drying may be higher than the rotation speed of the body 20a and the door 20b during the cleaning. During the drying process, the wafer storage container cleaning apparatus 1 performs the exhaust with an exhaust volume for the drying. Specifically, the adjustment device (not illustrated) of the first exhaust pipe 5f is controlled to exhaust the upper space above the partition plate 5j and the placement unit 5c with a first exhaust volume for the drying. Further, the adjustment device (not illustrated) of the second exhaust pipe 5g is controlled to exhaust the lower space below the partition plate 5j and the placement unit 5c with a second exhaust volume for the drying (step S203). This exhaust performed by the the first exhaust pipe 5f and the second exhaust pipe 5g during the drying is an example of a second exhaust. For example, the second exhaust pipe 5g performs the second exhaust to exhaust the storage space while supplying the hot blow to the inner side of the body 20a by the hot blow nozzle 5i1. When the drying performed by the second exhaust is completed, the rotation of the placement unit 5c stops.

It is believed that during the drying, the amount of water vapor generated in the cleaning chamber 5 is larger than that during the cleaning. Thus, the first exhaust volume for the drying is set to be larger than the first exhaust volume for the cleaning. Similarly, the second exhaust volume for the drying is set to be larger than the second exhaust volume for the cleaning. The first exhaust volume for the cleaning and the second exhaust volume for the cleaning are an example of a first exhaust volume. The first exhaust volume for the drying and the second exhaust volume for the drying are an example of a second exhaust volume.

The second standby process corresponds to the time period after the drying is completed until the lid unit 5b of the cleaning chamber 5 is opened. That is, in the case where the robot 3 is performing another transfer operation, the cleaning chamber 5 waits until the robot 3 is able to carry the body 20a and the door 20b from the cleaning chamber 5. During the second standby process, the wafer storage container cleaning apparatus 1 performs the exhaust with an exhaust volume for the second standby. Specifically, the adjustment device (not illustrated) of the first exhaust pipe 5f is controlled to exhaust the upper space above the partition plate 5j and the placement unit 5c with a first exhaust volume for the second standby. Further, the adjustment device (not illustrated) of the second exhaust pipe 5g is controlled to exhaust the lower space below the partition plate 5j and the placement unit 5c with a second exhaust volume for the second standby (step S204). Further, the first exhaust volume for the second standby and the second exhaust volume for the second standby are the same as the first exhaust volume for the first standby and the second exhaust volume for the first standby in the first standby process.

In the carry-out process, the exhaust is performed neither in the first exhaust pipe 5f nor in the second exhaust pipe 5g. The carry-out process corresponds to the time period after the lid unit 5b of the cleaning chamber 5 is opened to carry the body 20a and the door 20b out of the cleaning chamber 5, until the next body 20a and door 20b are carried into the cleaning chamber 5.

Furthermore, during the first standby process, the cleaning process, the drying process, and the second standby process, the exhaust volume when the exhaust is performed by the first exhaust pipe 5f and the exhaust volume when the exhaust is performed by the second exhaust pipe 5g may be adjusted such that the lower space has a negative pressure with respect to the upper space as described above. That is, the adjustment devices may adjust the exhaust volume when the first exhaust pipe 5f exhausts the upper space and the exhaust volume when the second exhaust pipe 5g exhausts the lower space, such that the pressure of the lower space becomes lower than the pressure of the upper space. However, the exhaust volume when the exhaust is performed by the first exhaust pipe 5f and the exhaust volume when the exhaust is performed by the second exhaust pipe 5g may be adjusted such that the lower space has a positive pressure with respect to the upper space. Further, the exhaust volume when the exhaust is performed by the first exhaust pipe 5f and the exhaust volume when the exhaust is performed by the second exhaust pipe 5g such that the pressure of the upper space and the pressure of the lower space are equal or substantially equal to each other.

In the wafer storage container cleaning apparatus 1 according to the present embodiment, the second exhaust pipe 5g evacuates the storage space of the body 20a during the cleaning of the inner side of the body 20a by the cleaning liquid nozzle 5h1. Thus, according to the wafer storage container cleaning apparatus 1, the residual particles in the inner side of the body 20a (storage space) of the FOUP 20 may be effectively reduced.

Further, the partition plate 5j is provided to partition the inside of the cleaning chamber body 5a into the upper cleaning space above the placement unit 5c and the lower cleaning space below the placement unit 5c, the holes 5c2 are formed in the placement unit 5c to communicate the storage space of the body 20a and the lower cleaning space with each other, and the lower cleaning space is exhausted by the second exhaust pipe 5g to exhaust the storage space of the body 20a. As a result, the upper cleaning space and the lower cleaning space may be exhausted separately, so that the inner side of the body 20a (the inside of the storage space) may be more efficiently exhausted, and therefore, the residual particles on the inner side of the body 20a may be effectively reduced.

Further, the hot blow nozzles 5i1, 5i2, and 5i3 are provided as a heated gas supply unit that supplies the heated gas to the inner side (storage space) and the outer side of the body 20a, and the second exhaust pipe 5g performs the first exhaust to exhaust the inner side of the body 20a during the cleaning of the inner side of the body 20a by the cleaning liquid nozzle 5h1 that is the cleaning liquid supply unit, and performs the second exhaust to exhaust the inner side of the body 20a with the (second) exhaust volume larger than the exhaust volume (first exhaust volume) of the first exhaust during the supply of heated gas to the inner side of the body 20a by the hot blow nozzle 5i1 (during the drying). Thus, the exhaust volume may be increased during the drying when the amount of water vapor generated on the inner side of the body 20a is likely to be larger than during the cleaning. As a result, the exhaust of the inner side of the body 20a may be appropriately performed during the cleaning and the drying, the residual particles in the storage space may be effectively reduced.

Further, the exhaust volume by the first exhaust pipe 5f and the exhaust volume by the second exhaust pipe 5g are adjusted such that the pressure for exhausting the lower cleaning space becomes lower than the pressure for exhausting the upper cleaning space. Further, during the cleaning of the inner side of the body 20a by the cleaning liquid nozzle 5h1 and during the supply of heated gas to the inner side of the body 20a by the hot blow nozzle 5i1, the exhaust volume by the first exhaust pipe 5f and the exhaust volume by the second exhaust pipe 5g are adjusted such that the pressure of the lower cleaning space becomes lower than the pressure of the upper cleaning space. As a result, the water vapor in the inner side of the body 20a, which is exhausted to the lower cleaning space through the exhaust by the second exhaust pipe 5g, may be prevented from entering the upper cleaning space where the body 20a is disposed. Therefore, the water vapor exhausted from the inner side of the body 20a may be prevented from adhering to and being contaminated on the outer side of the body 20a or the door 20b of the FOUP 20.

Further, the placement unit 5c has the circular shape in plan view, and is supported to be rotatable around the supporting shaft 5a3 provided at the center thereof. Further, the first drainage receiving unit 5d has the circularly annular recess shape in plan view, and is disposed such that the inner peripheral end of the first drainage receiving unit 5d is positioned between the holes 5c2 formed in the placement unit 5c and the rotating member 5a5, and the outer peripheral end of the first drainage receiving unit 5d is positioned between the outer periphery of the body 20a disposed on the placement surface 5cl in the state where the opening of the body 20a faces downward, and the outer peripheral end of the placement unit 5c. Further, between the outer periphery of the first drainage receiving unit 5d and the placement unit 5c, a gap is formed to allow the flow of the gas flowing from the storage space of the body 20a toward the second exhaust pipe 5g through the holes 5c2. As a result, the drainage of the cleaning liquid may be effectively discharged from the outer side and the inner side of the body 20a, separately, and at the same time, the storage space and the outer side of the body 20a may be effectively exhausted separately, so that the residual particles on the inner side of the body 20a may be further reduced.

From the foregoing, it will be appreciated that various embodiments of the present disclosure have been described herein for purposes of illustration, and that various Modifications may be made without departing from the scope and spirit of the present disclosure. Accordingly, the various embodiments disclosed herein are not intended to be limiting, with the true scope and spirit being indicated by the following claims.

What is claimed is:

1. A wafer storage container cleaning apparatus comprising:
a cleaning chamber configured to accommodate a body of a wafer storage container, the body including a storage space storing semiconductor wafers and an opening of the storage space;
a stage disposed inside the cleaning chamber, having a placement surface on which the body is disposed in a state where the opening faces downward, and configured to support the body by the placement surface;
a cleaning liquid supply configured to supply a cleaning liquid to an inner side of the body that is a wall surface surrounding the storage space, and an outer side of the body that is an outer wall surface of the body, thereby cleaning the inner side and the outer side of the body;
a first drainage receiver configured to receive a drainage that is the cleaning liquid after cleaning the inner side of the body, and discharge the received drainage to an outside;
a second drainage receiver configured to receive a drainage that is the cleaning liquid after cleaning the outer side of the body, and discharge the received drainage to the outside; and
an exhaust configured to exhaust the storage space formed by at least the inner side of the body.

2. The wafer storage container cleaning apparatus according to claim 1, wherein the exhaust exhausts the storage space during the cleaning of the inner side of the body by the cleaning liquid supply.

3. The wafer storage container cleaning apparatus according to claim 1, further comprising:
a partition plate dividing an inside of the cleaning chamber into an upper space above the stage and a lower space below the stage,
wherein in the stage, an opening is formed to communicate the storage space and the lower space with each other, and
the exhaust exhausts the lower space, thereby exhausting the storage space.

4. The wafer storage container cleaning apparatus according to claim 1, further comprising:
a heated gas supply configured to supply a heated gas to the inner side and the outer side of the body,
wherein the exhaust performs a first exhaust with a first exhaust volume to exhaust the storage space during the cleaning of the inner side of the body by the cleaning liquid supply, and performs a second exhaust with a second exhaust volume larger than the first exhaust volume to exhaust the storage space during the supply of the heated gas to the inner side of the body by the heated gas supply.

5. The wafer storage container cleaning apparatus according to claim 3, wherein the exhaust further exhausts the upper space, and adjusts an exhaust volume when exhausting the upper space and an exhaust volume when exhausting the lower space to make a pressure in the lower space lower than a pressure in the upper space.

6. The wafer storage container cleaning apparatus according to claim 5, further comprising:
a heated gas supply configured to supply a heated gas to the inner side and the outer side of the body,
wherein the exhaust adjusts an exhaust volume when exhausting the upper space and an exhaust volume when exhausting the lower space to make a pressure in the lower space lower than a pressure in the upper space, during the cleaning of the inner side of the body by the cleaning liquid supply and during the supply of the heated gas to the inner side of the body by the heated gas supply.

7. The wafer storage container cleaning apparatus according to claim 3, wherein the stage has a circular shape in plan view, and is supported to be rotatable about a rotation axis provided at a center thereof,
the first drainage receiver has a circularly annular recess shape in plan view, and is disposed such that an inner peripheral end of the first drainage receiver is positioned between the opening formed in the stage and the rotation axis, and an outer peripheral end of the first drainage receiver is positioned between an outermost periphery of the body disposed on the placement surface in a state where the opening of the body faces downward, and an outer peripheral end of the stage, and
between an outer periphery of the first drainage receiver and the stage, a gap is formed to allow a flow of a gas flowing from the storage space toward the exhaust through the opening of the stage.
